(19) United States
(12) Patent Application Publication
(10) Pub. No.: US 2016/0071865 A1
(43) Pub. Date: Mar. 10, 2016

(54) SEMICONDUCTOR MEMORY DEVICE

(71) Applicant: Kabushiki Kaisha Toshiba, Minato-ku (JP)

(72) Inventors: Yoshihiro YANAI, Yokkaichi (JP); Yoshiro Shimojo, Yokkaichi (JP); Masaru Kito, Kuwana (JP); Masaru Kidoh, Yokkaichi (JP)

(73) Assignee: Kabushiki Kaisha Toshiba, Minato-ku (JP)

(21) Appl. No.: 14/817,852

(22) Filed: Aug. 4, 2015

(30) Foreign Application Priority Data
Sep. 4, 2014 (JP) 2014-180504

(51) Int. Cl. H01L 27/115; H01L 23/535; H01L 27/02

(52) U.S. Cl. CPC H01L 27/11578; H01L 27/0207; H01L 23/535

(57) ABSTRACT

According to one embodiment, the memory strings are disposed in a first direction and a second direction. The source layers extend in the second direction on the memory strings and are separated in the first direction. The bit lines extend in the first direction on the memory strings and are separated in the second direction. The memory string includes a first columnar section, a second columnar section, and a connecting section. The stacked body includes a plurality of blocks separated from one another in the first direction. The source layer is connected to an upper end of the first columnar section. The bit line is connected to an upper end of the second columnar section of the memory string belonging to a block selected out of the plurality of blocks.

### CROSS-REFERENCE TO RELATED APPLICATION

This application is based upon and claims the benefit of priority from Japanese Patent Application No. 2014-180504, filed on Sep. 4, 2014; the entire contents of which are incorporated herein by reference.

### FIELD

Embodiments described herein relate generally to a semiconductor memory device.

### BACKGROUND

A memory device having a three-dimensional structure has been proposed. In the memory device, a memory hole is formed in a stacked body including a plurality of electrode layers stacked via insulating layers. The electrode layers function as control gates in memory cells. A silicon body functioning as a channel is provided on the sidewall of the memory hole via a charge storage film.

Writing throughput in such a three-dimensional memory device depends on the number of memory strings connected to one bit line.

### BRIEF DESCRIPTION OF THE DRAWINGS

FIG. 1 is a schematic plan view of a semiconductor memory device of an embodiment;

FIG. 2 is a schematic plan view of the semiconductor memory device of the embodiment;

FIG. 3 is a schematic sectional view of the semiconductor memory device of the embodiment;

FIG. 4 is an enlarged schematic sectional view of a columnar section of the semiconductor memory device of the embodiment; and

FIG. 5 is a schematic plan view of the semiconductor memory device of the embodiment.

### DETAILED DESCRIPTION

According to one embodiment, a semiconductor memory device includes a stacked body, a plurality of memory strings, a plurality of source layers, and a plurality of bit lines. The stacked body includes a plurality of electrode layers stacked via an insulating layer. The memory strings are disposed in a first direction orthogonal to a stacking direction of the stacked body, and a second direction crossing the stacking direction and the first direction. The source layers extend in the second direction on the memory strings and are separated in the first direction. The bit lines extend in the first direction on the memory strings and are separated in the second direction. The memory string includes a first columnar section, a second columnar section, and a connecting section. The first columnar section includes a first semiconductor body extending in the stacking direction and a first charge storage film provided between the first semiconductor body and the electrode layers. The second columnar section includes a second semiconductor body extending in the stacking direction and a second charge storage film provided between the second semiconductor body and the electrode layers. The connecting section connects a lower end of the first semiconductor body and a lower end of the second semiconductor body. The stacked body includes a plurality of blocks separated from one another in the first direction. The source layer is connected to an upper end of the first columnar section. The bit line is connected to an upper end of the second columnar section of the memory string belonging to a block selected out of the plurality of blocks.

Embodiments are described below with reference to the drawings. Note that, in the figures, the same components are denoted by the same reference numerals and signs.

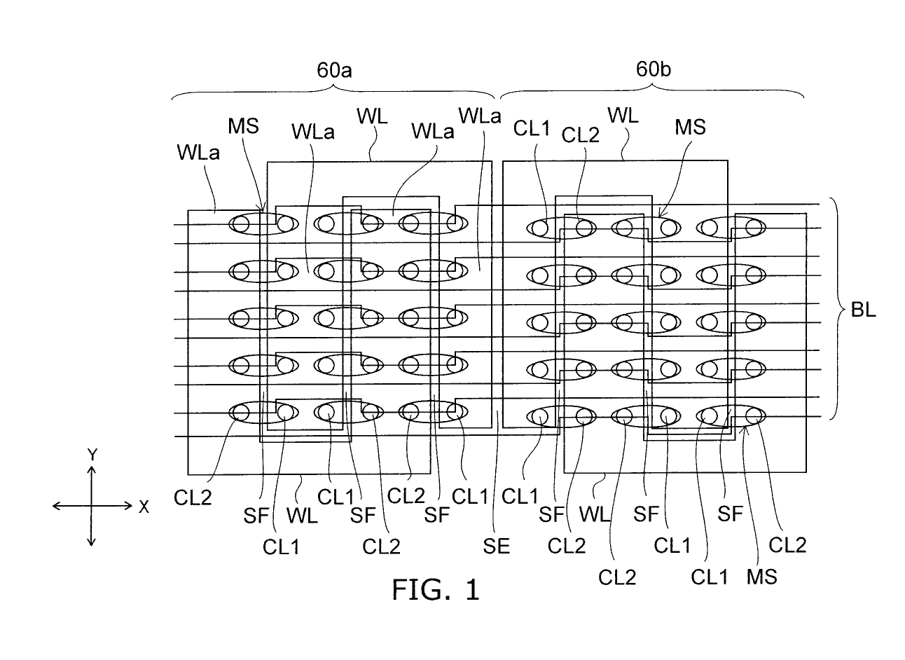

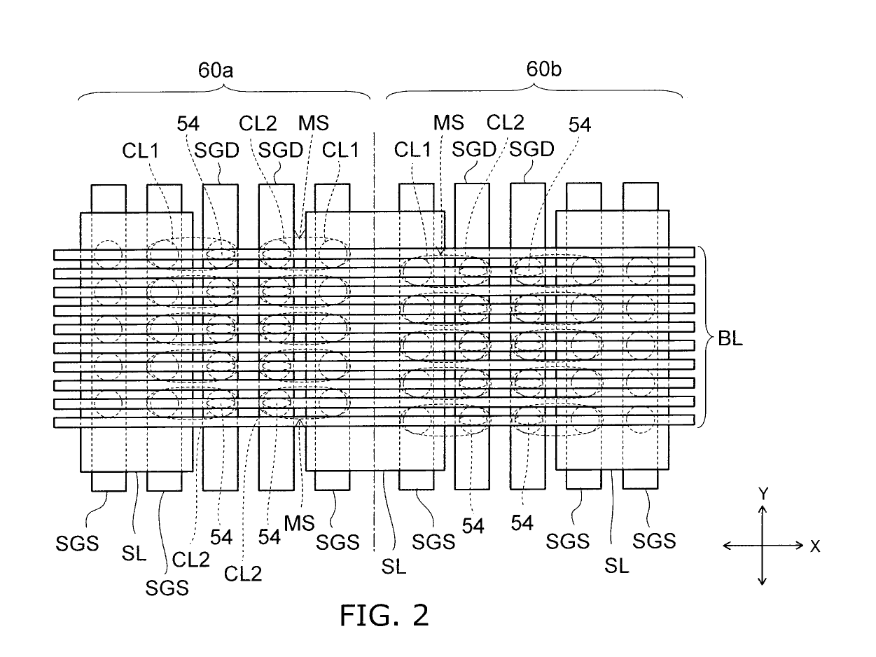

FIGS. 1 and 2 are schematic plan views of a memory cell array of a semiconductor memory device of an embodiment.

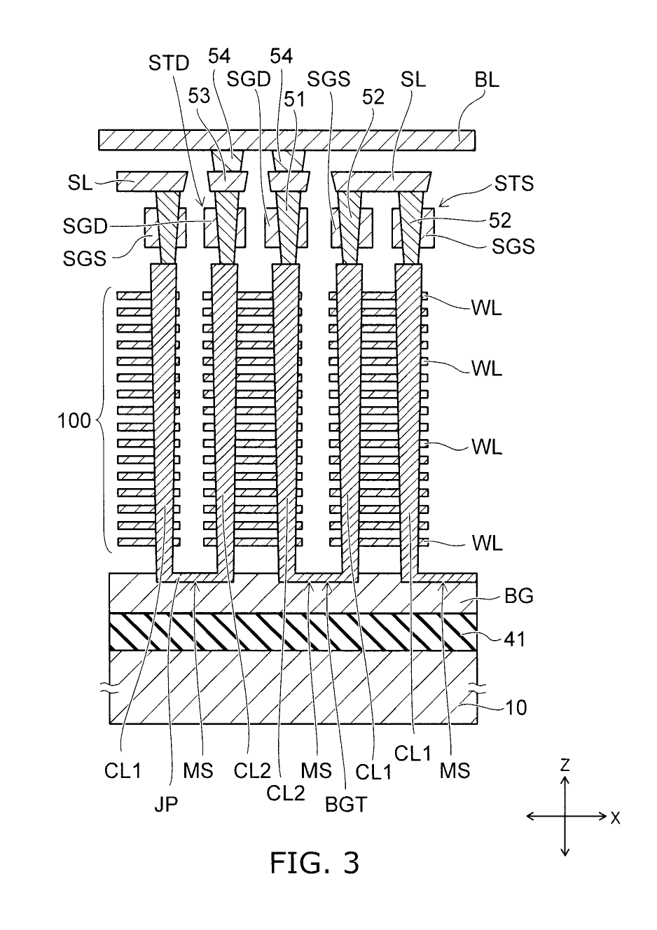

FIG. 3 is a schematic sectional view of the memory cell array of the embodiment. In FIG. 3, an interelectrode insulating layer, an insulating separation film, an interlayer insulating layer, and the like are not shown.

A stacked body 100 including a plurality of layers of electrode layers WL is provided on a substrate 10. Two directions that are orthogonal to each other in a plane parallel to a major surface of the substrate 10 are represented as an X-direction and a Y-direction. A direction that is orthogonal to the X-direction and the Y-direction (an XY plane) and in which the plurality of layers of the electrode layers WL are stacked is represented as Z-direction (a stacking direction).

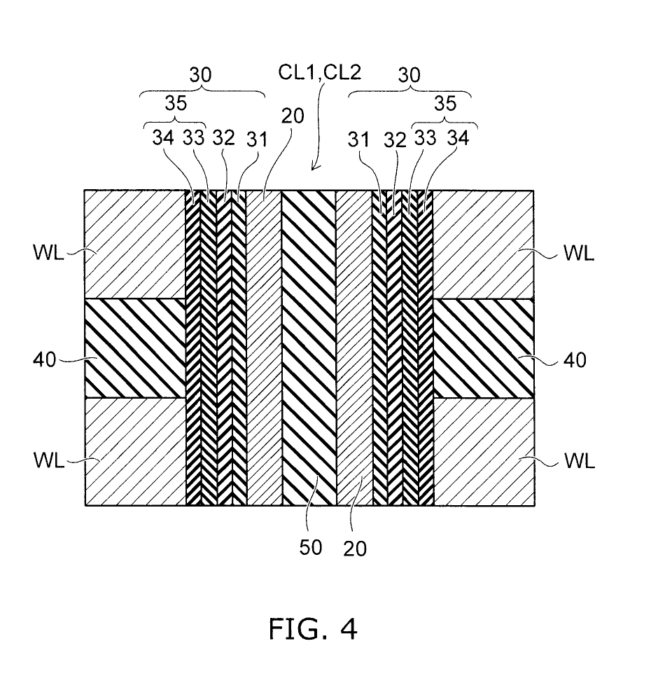

The memory cell array includes the stacked body 100 in which the electrode layers WL and a plurality of insulating layers 40 (shown in FIG. 4) are alternately stacked. The insulating layers 40 are provided among the electrode layers WL adjacent to one another in the stacking direction (the Z direction). As shown in FIG. 3, the stacked body 100 is provided on a back gate BG functioning as a lower gate layer. Note that the number of layers of the electrode layers WL shown in the figure is an example. The number of layers of the electrode layers WL may be any number.

The back gate BG is provided on the substrate 10 via an insulating layer 41. The back gate BG and the electrode layers WL are layers containing silicon as a main component. Further, the back gate BG and the electrode layers WL contain, for example, boron as impurities for imparting conductivity to a silicon layer. The electrode layers WL may contain metal silicide. Alternatively, the electrode layers WL are metal layers. The insulating layers 40 mainly contain, for example, silicon oxide.

The memory cell array includes a plurality of memory strings MS. One memory string MS is formed in a U shape including a pair of a first columnar section CL1 and a second columnar section CL2 extending in the Z-direction and a connecting section JP that couples respective lower ends of the first columnar section CL1 and the second columnar section CL2. Each of the first columnar section CL1 and the second columnar section CL2 is formed in, for example, a columnar or elliptical columnar shape, pierces through the stacked body 100, and reaches the back gate BG.

A drain-side columnar section 51 and a drain-side select gate SGD are provided on the second columnar section CL2 in the U-shaped memory string MS. A source-side columnar section 52 and a source-side select gate SGS are provided on the first columnar section CL1.

The drain-side columnar section 51 pierces through the drain-side select gate SGD and reaches the upper end of the second columnar section CL2. The source-side columnar section 52 pierces through the source-side select gate SGS and reaches the upper end of the first columnar section CL1.

The drain-side select gate SGD and the source-side select gate SGS are layers containing silicon as a main component. Further, the drain-side select gate SGD and the source-side select gate SGS contain, for example, boron as impurities for imparting conductivity to a silicon layer.

The drain-side select gate SGD and the source-side select gate SGS functioning as an upper select gate layer and the back gate BG functioning as a lower select gate layer are thicker than one layer of the electrode layer WL.

The drain-side select gate SGD and the source-side select gate SGS are separated in the X-direction. As shown in FIG. 2, the drain-side select gate SGD and the source-side select gate SGS extend in the Y-direction.

The stacked body 100 including the plurality of layers of the electrode layers WL is separated in the X-direction between the first columnar section CL1 and the second columnar section CL2.

A source layer SL is provided on the source-side columnar section 52. The source layer SL is connected to the source-side columnar section 52.

A interconnection layer 53 is provided on the drain-side columnar section 51. A bit line contact section 54 is provided on the interconnection layer 53. The interconnection layer 53 is provided in the same layer as the source layer SL. A bit line BL is provided on the interconnection layer 53 and the source layer SL. The bit line BL is connected to the drain-side columnar section 51 via the bit line contact section 54 and the interconnection layer 53.

FIG. 4 is an enlarged schematic sectional view of a part of the first columnar section CL1 and the second columnar section CL2. The first columnar section CL1 and the second columnar section CL2 have the same configuration.

The columnar section CL1, CL2 includes a channel body 20 functioning as a semiconductor body and a memory film 30 provided in order from the center axis side toward the outer side in the diameter direction. The channel body 20 is, for example, a silicon film. The impurity concentration of the channel body 20 is lower than the impurity concentration of the electrode layers WL.

The memory film 30 includes a block insulating film 35, a charge storage film 32, and a tunnel insulating film 31. The block insulating film 35, the charge storage film 32, and the tunnel insulating film 31 are provided in order from the electrode layers WL side between the electrode layers WL and the channel body 20.

The channel body 20 is provided in a cylindrical shape extending in the stacking direction of the stacked body 100. The memory film 30 is provided in a cylindrical shape to surround the outer circumferential surface of the channel body 20 while extending in the stacking direction of the stacked body 100. The electrode layers WL surround the channel body 20 via the memory film 30. A core insulating film 50 is provided on the inner side of the channel body 20. The core insulating film 50 is, for example, a silicon oxide film.

The block insulating film 35 is in contact with the electrode layers WL. The tunnel insulating film 31 is in contact with the channel body 20. The charge storage film 32 is provided between the block insulating film 35 and the tunnel insulating film 31.

The channel body 20 functions as a channel in memory cells. The electrode layers WL function as control gates of the memory cells. The charge storage film 32 functions as a data memory layer that accumulates charges injected from the channel body 20. That is, memory cells having a structure in which the control gates surround the channel are formed in crossing portions of the channel body 20 and the electrode layers WL.

The semiconductor memory device of the embodiment is a nonvolatile semiconductor memory device that can electrically freely perform erasing and writing of data and can retain stored content even if a power supply is turned off.

The memory cell is, for example, a memory cell of a charge trap type. The charge storage film 32 includes a large number of trap sites that trap charges. The charge storage film 32 is, for example, a silicon nitride film.

The tunnel insulating film 31 functions as a potential barrier when charges are injected into the charge storage film 32 from the channel body 20 or when charges stored in the charge storage film 32 diffuse to the channel body 20. The tunnel insulating film 31 is, for example, a silicon oxide film.

Alternatively, as the tunnel insulating film, a stacked film (an ONO film) having a structure in which a silicon nitride film is sandwiched by a pair of silicon oxide films may be used. When the ONO film is used as the tunnel insulating film, compared with a single layer of a silicon oxide film, an erasing operation can be performed in a low electric field.

The block insulating film 35 prevents the charges stored in the charge storage film 32 from diffusing to the electrode layers WL. The block insulating film 35 includes a cap film 34 provided in contact with the electrode layers WL and a block film 33 provided between the cap film 34 and the charge storage film 32.

The block film 33 is, for example, a silicon oxide film. The cap film 34 is a film having a dielectric constant higher than the dielectric constant of silicon oxide and is, for example, a silicon nitride film. By providing such a cap film 34 in contact with the electrode layers WL, it is possible to suppress back tunnel electrons injected from the electrode layers WL during erasing. That is, by using a stacked film of the silicon oxide film and the silicon nitride film as the block insulating film 35, it is possible to improve a charge blocking property.

As shown in FIG. 3, a drain-side select transistor STD is provided on the second columnar section CL2 in the U-shaped memory string MS. A source-side select transistor STS is provided on the first columnar section CL1.

The drain-side select transistor STD and the source-side select transistor STS are vertical transistors in which an electric current flows in the stacking direction of the stacked body 100 (the Z-direction).

The drain-side select gate SGD surrounds the drain-side columnar section 51 and functions as a gate electrode of the drain-side select transistor STD. The drain-side columnar section 51 includes a cylindrical channel connected to the channel body 20 of the second columnar section CL2 and a gate insulating film provided between the channel and the drain-side select gate SGD. A channel of the drain-side select transistor STD is connected to the bit line BL via the interconnection layer 53 and the bit line contact section 54.

The source-side select gate SGS surrounds the source-side columnar section 52 and functions as a gate electrode of the source-side select transistor STS. The source-side columnar section 52 includes a cylindrical channel connected to the channel body 20 of the first columnar section CL1 and a gate insulating film provided between the channel and the source-side select gate SGS. A channel of the source-side select transistor STS is connected to the source layer SL.

A back gate transistor BGT is provided in the connecting section JP of the memory string MS. The back gate BG functions as a gate electrode of the back gate transistor BGT. The memory film 30 provided in the back gate BG functions as a gate insulating film of the back gate transistor BGT.

A plurality of memory cells including the electrode layers WL in the respective layers as control gates are provided between the drain-side select transistor STD and the back gate transistor BGT. Similarly, a plurality of memory cells including the electrode layers WL in the respective layers as control gates are also provided between the back gate transistor BGT and the source-side select transistor STS.

The plurality of memory cells, the drain-side select transistor STD, the back gate transistor BGT, and the source-side select transistor STS are connected in series through the channel body 20 and configures U-shaped one memory string MS. A plurality of the memory strings MS are arrayed in the X-direction and the Y-direction, whereby a plurality of memory cells are three-dimensionally provided in the X-direction, the Y-direction, and the Z-direction.

An example of a plane pattern of the electrode layers WL in the respective layers is shown in FIG. 1. The electrode layers WL in the respective layers are processed into a comb-shaped pattern including a plurality of fingers WLa extending in the Y-direction.

For example, two comb-shaped patterns are combined to form one unit. The fingers WLa of the other comb-shaped pattern are located among the plurality of fingers WLa of one comb-shaped pattern. The plurality of fingers WLa of the two comb-shaped patterns are separated from each other in the X-direction by a separating section SF extending in the Y-direction.

The stacked body including the plurality of layers of the electrode layers WL is separated into a plurality of blocks 60a and 60b. The plurality of blocks 60a and 60b are separated in the X-direction by a separating section SE extending in the Y-direction. In FIG. 2, a boundary between the blocks 60a and 60b is represented by an alternate long and short dash line.

In FIG. 1, for example, only two blocks 60a and 60b are shown. However, a plurality of the blocks 60a and 60b shown in FIG. 1 are repeatedly arrayed in the X-direction.

Each of the blocks 60a and 60b may include a combination of two or more pairs of comb-shaped patterns.

In the fingers WLa of the electrode layers WL, the columnar sections CL1 and CL2 of the memory string MS are formed. In each of the blocks 60a and 60b, a plurality of the columnar sections CL1 and CL2 are disposed in, for example, a square lattice in the X-direction and the Y-direction.

A direction in which the first columnar section CL1 and the second columnar section CL2 belonging to one same memory string MS is parallel to the X-direction. The first columnar section CL1 and the second columnar section CL2 belonging to the one same memory string MS are respectively formed in the fingers WLa of different comb-shaped patterns.

The separating section SF is interposed between the first columnar section CL1 and the second columnar section CL2 belonging to the one same memory string MS. Therefore, the control gate (the electrode layer WL) of the memory cell formed in the first columnar section CL1 and the control gate (the electrode layer WL) of the memory cell formed in the second columnar section CL2, which are located across the separating section SF, can be respectively independently controlled by the different comb-shaped patterns.

As shown in FIG. 2, a plurality of the source layers SL extend in the Y-direction on the memory strings MS and are separated in the X-direction.

Under the source layer SL, the source-side select gate SGS extends in the Y-direction. The interconnection layer 53 shown in FIG. 3 is provided in the same layer as the source layer SL in a region where the source layer SL is not provided. Under the interconnection layer 53, the drain-side select gate SGD extends in the Y-direction.

As shown in FIG. 2, a plurality of the bit lines BL extend in the X direction on the memory strings MS and are separated in the Y-direction. Each of the bit lines BL extends straightly in the X-direction. The X-direction and the Y-direction cross and are, for example, orthogonal to each other in a plane parallel to the substrate 10.

Each of the bit lines BL is connected to, via the bit line contact sections 54, the upper ends of the second columnar sections CL2 of the memory string MS belonging to a block selected out of the plurality of blocks 60a and 60b.

The blocks 60a and the blocks 60b are alternately arranged in the X-direction. In the example shown in FIG. 2, the bit lines BL connected to the second columnar sections CL2 belonging to the block 60a and the bit lines BL connected to the second columnar sections CL2 belonging to the block 60b adjacent to the block 60a are alternately arranged in the Y-direction.

The bit line BL connected to the second columnar section CL2 belonging to the block 60a is also connected to the second columnar section CL2 belonging to a block (not shown in the figure) located on the right of the block 60b in FIG. 2.

The bit line BL connected to the second columnar section CL2 belonging to the block 60b is also connected to the second columnar section CL2 belonging to a block (not shown in the figure) located on the left of the block 60a in FIG. 2.

That is, each of the bit lines BL is connected to the upper ends of the second columnar sections CL2 of the memory strings MS belonging to every other block among the plurality of blocks arranged in the X-direction.

Alternatively, each of the bit lines BL may be connected to the upper ends of the second columnar sections CL2 of the memory strings MS belonging to every n (n is an integer not less than 2) blocks among the plurality of blocks arranged in the X-direction.

According to the embodiment, the number of the memory strings MS connected to one bit line BL decreases compared with a configuration in which each of the bit lines BL is connected to the second columnar sections CL2 of all the memory strings MS arrayed in the X-direction. Therefore, it is possible to attain improvement of a processing ability, in particular, writing throughput.

A pitch in the Y-direction of the bit line contact sections 54 is larger than a pitch in the Y-direction of the bit lines BL.

An upper limit of the diameter of the columnar section CL2 can be allowed up to approximately a double of the width of the bit line BL. The width in the Y-direction of the bit line contact section 54 is substantially the same as the width of the bit line BL.

In the example shown in FIG. 2, the positions in the Y-direction of the memory strings MS are not aligned with each other between the blocks 60a and 60b adjacent to each other. In one block 60a or 60b, a plurality of the first columnar sections CL1 and a plurality of the second columnar sections CL2 are disposed in a square lattice in the X-direction and the Y-direction.

The columnar sections CL1 and CL2 are formed in a memory hole formed by, for example, an RIE (Reactive Ion Etching) method.

Latent images of a plurality of line-and-space patterns extending in the X-direction are exposed and transferred onto a resist functioning as a mask for processing of the stacked body 100. Further, latent images of a plurality of line-and-space patterns extending in the Y-direction orthogonal to the X-direction are exposed and transferred onto the resist. An exposure amount is larger in cross points of line pattern latent images orthogonal to one another than in line portions. Cross points of space pattern latent images orthogonal to one another are not subjected to exposure. The cross points of the line pattern latent images or the cross points of the space pattern latent images are soluble in developing solution.

Therefore, after the resist is developed, a plurality of holes (openings) disposed in a square lattice in the X-direction and the Y-direction are formed in the resist. By etching the stacked body 100 with the RIE method using the resist as a mask, a plurality of memory holes disposed in a square lattice in the X-direction and the Y-direction can be formed.

Since the cross point exposure by the orthogonal line-and-space patterns can be used in the exposure, it is possible to control the positions and the shapes of the plurality of memory holes at high accuracy. Therefore, a short-circuit failure of the columnar sections CL1 and CL2 adjacent to each other less easily occurs.

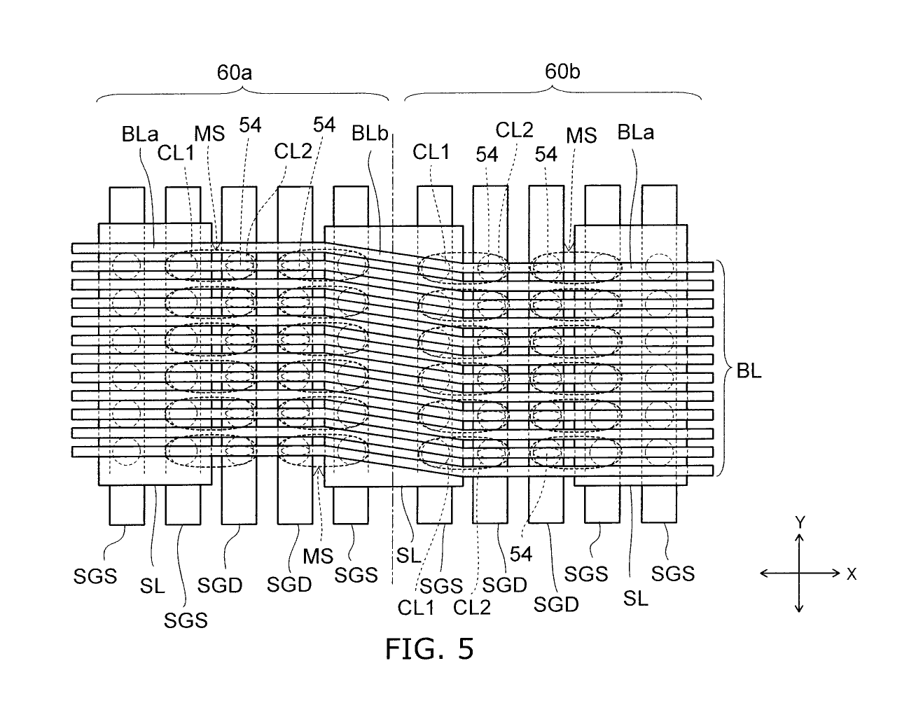

FIG. 5 is a schematic plan view of a memory cell array of another embodiment.

In the embodiment shown in FIG. 5, the positions in the Y-direction of the memory strings MS are aligned with each other between the blocks 60a and 60b adjacent to each other. Therefore, in an entire memory cell array including a plurality of blocks, the plurality of first columnar sections CL1 and the plurality of second columnar sections CL2 are disposed in a square lattice in the X-direction and the Y-direction.

The plurality of bit lines BL extend in the X-direction on the memory strings MS and are separated in the Y-direction. A pitch in the Y-direction of the bit line contact sections 54 is larger than a pitch in the Y-direction of the bit lines BL.

Each of the bit lines BL includes first portions BLa parallel to the X-direction and second portions BLb inclined with respect to the X-direction and the Y-direction. The first portions BLa and the second portions BLb are alternately connected in the X-direction.

The first portion BLa is located on the second columnar sections CL2 to which the bit line BL is connected. The second portion BLb is located on a boundary region of the blocks. Each of the bit lines BL bends in the boundary region of the blocks while extending in the X-direction as a whole.

In the embodiment shown in FIG. 5 as well, each of the bit lines BL is connected to, via the bit line contact sections 54, the upper ends of the second columnar sections CL2 of the memory string MS belonging to a block selected out of the plurality of blocks 60a and 60b.

In the example shown in FIG. 5, the bit lines BL connected to the second columnar sections CL2 belonging to the block 60a and the bit lines BL connected to the second columnar sections CL2 belonging to the block 60b adjacent to the block 60a are alternately arranged in the Y-direction.

The bit line BL connected to the second columnar section CL2 belonging to the block 60a is also connected to the second columnar section CL2 belonging to a block (not shown in the figure) located on the right of the block 60b in FIG. 5.

The bit line BL connected to the second columnar section CL2 belonging to the block 60b is also connected to the second columnar section CL2 belonging to a block (not shown in the figure) located on the left of the block 60a in FIG. 5.

That is, each of the bit lines BL is connected to the upper ends of the second columnar sections CL2 of the memory strings MS belonging to every other block among the plurality of blocks arranged in the X-direction.

Alternatively, each of the bit lines BL may be connected to the upper ends of the second columnar sections CL2 of the memory strings MS belonging to every n (n is an integer not less than 2) blocks among the plurality of blocks arranged in the X-direction.

In the embodiment shown in FIG. 5 as well, the number of the memory strings MS connected to one bit line BL decreases compared with a configuration in which each of the bit lines BL is connected to the second columnar sections CL2 of all the memory strings MS arrayed in the X-direction. Therefore, it is possible to attain improvement of a processing ability, in particular, writing throughput.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a stacked body including a plurality of electrode layers stacked via an insulating layer;
a plurality of memory strings disposed in a first direction orthogonal to a stacking direction of the stacked body, and a second direction crossing the stacking direction and the first direction;
a plurality of source layers extending in the second direction on the memory strings and separated in the first direction; and
a plurality of bit lines extending in the first direction on the memory strings and separated in the second direction,
the memory string including:
a first columnar section including a first semiconductor body extending in the stacking direction and a first charge storage film provided between the first semiconductor body and the electrode layers;
a second columnar section including a second semiconductor body extending in the stacking direction and a second charge storage film provided between the second semiconductor body and the electrode layers; and
a connecting section connecting a lower end of the first semiconductor body and a lower end of the second semiconductor body,
the stacked body including a plurality of blocks separated from one another in the first direction,
the source layer being connected to an upper end of the first columnar section, and
the bit line being connected to an upper end of the second columnar section of the memory string belonging to a block selected out of the plurality of blocks.

2. The device according to claim 1, wherein the bit line is connected to an upper end of the second columnar section belonging to every n (n is an integer not less than 1) blocks among the plurality of blocks arranged in the first direction.

3. The device according to claim 1, wherein the bit line extends straightly in the first direction.

4. The device according to claim 1, wherein a pitch in the second direction of contact sections where the second columnar section and the bit lines are connected is larger than a pitch in the second direction of the bit lines.

5. The device according to claim 1, wherein, in the block, a plurality of the first columnar sections and a plurality of the second columnar sections are disposed in a square lattice in the first direction and the second direction.

6. The device according to claim 1, wherein the memory string includes:
a source-side select gate provided between the first columnar section and the source layer, and extending in the second direction; and
a drain-side select gate provided between the second columnar section and the bit line, and extending in the second direction.

7. The device according to claim 6, wherein the memory string includes:
a source-side columnar section piercing through the source-side select gate, and connected to the first columnar section and the source layer; and
a drain-side columnar section piercing through the drain-side select gate, and connected to the second columnar section and the bit line.

8. The device according to claim 7, further comprising an interconnection layer provided between the drain-side columnar section and the bit line, and connected to the drain-side columnar section and the bit line.

9. The device according to claim 8, wherein the interconnection layer is provided in a same layer as the source layer.

10. The device according to claim 1, wherein the electrode layers are divided in the second direction between the first columnar section and the second columnar section.

11. The device according to claim 1, wherein
the electrode layers include first electrode layers and second electrode layers,
the first columnar section pierces through the first electrode layers,
the second columnar section belonging to a same memory string as the first columnar section pierces through the second electrode layers, and
the first electrode layers and the second electrode layers are separated from each other.

12. The device according to claim 1, wherein
the plurality of blocks include a plurality of first blocks and a plurality of second blocks alternately arranged in the first direction,
the bit lines include first bit lines and second bit lines,
the first bit lines are connected to the second columnar section belonging to the first block,
the second bit lines are connected to the second columnar section belonging to the second block, and
the first bit lines and the second bit lines are alternately arranged in the second direction.

13. The device according to claim 12, wherein positions in the second direction of the memory string of the first block and the memory string of the second block are not aligned.

14. The device according to claim 1, wherein the bit lines include a first portion parallel to the first direction and a second portion inclined with respect to the first direction.

15. The device according to claim 14, wherein the second portion is located in a boundary region of the plurality of blocks.

16. The device according to claim 14, wherein the first portion is located on the second columnar section.

17. The device according to claim 14, wherein
the plurality of blocks include a plurality of first blocks and a plurality of second blocks alternately arranged in the first direction, and
positions in the second direction of the memory string of the first block and the memory string of the second block are aligned.

18. The device according to claim 14, wherein the first portion and the second portion are alternately connected in the first direction.
